(19) United States
(12) Patent Application Publication
(10) Pub. No.: US 2006/0241880 A1
(43) Pub. Date: Oct. 26, 2006

(54) Methods and apparatus for monitoring power flow in a conductor

(76) Inventors: J. Bradford Forth, Victoria (CA); Daniel A. Cumming, Victoria (CA); Simon H. Lightbody, Victoria (CA)

Correspondence Address: BRINKS HOFER GILSON & LIONE/PML, PO BOX 10395, CHICAGO, IL, 60610, US

(21) Appl. No.: 11/333,822

(22) Filed: Jan. 17, 2006

Related U.S. Application Data
(63) Continuation of application No. PCT/US04/23006, filed on Jul. 16, 2004.
(60) Provisional application No. 60/488,700, filed on Jul. 18, 2003.
(60) Provisional application No. 60/554,188, filed on Mar. 18, 2004.

(51) Int. Cl. G01R 21/06

(52) U.S. Cl. 702/60

(57) ABSTRACT

An energy monitoring device includes means for sensing current in a power line and generating an analog signal representative thereof. The energy monitoring device includes means for generating a digital representation of the current. The energy monitoring device includes means for assuming a voltage value and calculating at least one measure of power consumption using the sensed current and the assumed voltage. A method executable by said energy monitoring device is also disclosed.

### RELATED APPLICATIONS

This application is a continuation under 35 U.S.C. §§ 120, 271 and 365 of Patent Cooperation Treaty patent application no. PCT/US2004/023006, filed Jul. 16, 2004, which was published at WO 2005/008181, in English. This application is further related to and claims the benefit of the filing date under 35 U.S.C. § 119(e) of Provisional U.S. Patent Application Ser. No. 60/488,700, filed Jul. 18, 2003 (Attorney Ref. No 6270/115) and Ser. No. 60/554,188, filed Mar. 18, 2004 (Attorney Ref. No 6270/116) and this application is a continuation in part under 35 U.S.C. § 120 and § 365(c) of PCT International Patent Application Designating the U.S. Serial No. PCT/CA/000705 entitled “Time Coordinated Energy Monitoring System Utilizing Communications Links” filed May 11, 2004 which claimed the benefit under 35 U.S.C. § 119(e) of Provisional U.S. Patent Application Ser. No. 60/469,766, filed May 12, 2003, all of which are hereby incorporated by reference.

PCT International Patent Application Designating the U.S. Serial No. PCT/CA/000705 incorporated by reference the following U.S. patent application which is also incorporated by reference herein:

U.S. patent application Ser. No. 10/843,256, “Wireless Communications System Incorporating Intelligent Electronic Devices”, (Attorney Ref. No. 6270/142), filed May 11, 2004.

The following U.S. patent application is also incorporated by reference herein:

U.S. patent application Ser. No. 10/892,837 (Attorney Ref. No. 6270/147), filed Jul. 16, 2004.

### BACKGROUND

In facilities, e.g. buildings or installations, where a significant amount of power is used among a variety of units, it would be desirable to allow the building owner to allocate energy costs to the different units, i.e. consumers, within the facility. For a commercial office building, these units may include the different tenants within the building or the common loads for the facility, such as the elevators or HVAC systems. For an industrial facility, these units may include the different production lines, machines or processes within the facility. As opposed to allocating costs based on a fixed or formulaic approach (such as pro-rata, e.g. dollars per square foot or based on the theoretical consumption of a process/machine), an allocation based on actual measurements using appropriate monitoring devices may result in more accurate and useful information as well as a more equitable cost distribution.

Both installation and ongoing, i.e. operational and maintenance, costs for these monitoring devices are important considerations in deciding whether a monitoring system is worth the investment. While monitoring devices may be read manually, which does not increase the installation cost, manual data collection may increase on-going/operational costs. Alternatively, monitoring devices may be interconnected and be automatically read via a communications link. However, typical communication links require wiring to interconnect the devices which increases the installation cost. In addition, a particular tenant in the building may wish to verify that they are being billed correctly by reading the energy meter or other energy monitoring device that is accumulating their energy usage. This may be a straightforward, although labor intensive and cumbersome, process with a typical energy meter which provides a display viewable by the tenant.

Emerging wireless mesh (or ad-hoc) networking technologies can be used to reduce the installation costs of monitoring devices while providing for automated data collection. Also called mesh topology or a mesh network, mesh is a network topology in which devices are connected with many redundant interconnections between network nodes. Effectively, each network node acts as a repeater/router with respect to received communications where the device is not the intended recipient in order to facilitate communications between devices across the network. Using wireless interconnections permits simpler and cost-effective implementation of mesh topologies wherein each device is a node and wirelessly interconnects with at least some of the other devices within its proximity using RF based links. Mesh networking technologies generally fall into two categories: high-speed, high bandwidth; and low speed, low bandwidth, low power. The first category of devices are typically more complex and costly that the second. Since energy monitoring does not typically require high speed/high bandwidth communication, the second category of devices is often sufficient in terms of data throughput.

Energy monitoring devices may include electrical energy meters that measure at least one of kWh, kVAh, kVARh, kW demand, kVA demand, kVAR demand, voltage, current, etc. Energy monitoring devices may also include devices that measure the consumption of water, air, gas and/or steam.

### SUMMARY

The present invention is defined by the following claims, and nothing in this section should be taken as a limitation on those claims. By way of introduction, the preferred embodiments described below relate to a monitoring device for monitoring electrical energy consumed by an electrical load. The monitoring device includes: a current sensor operative to sense actual current flow in at least one power line which is supplying electrical energy to the load, the at least one power line being further characterized by an actual voltage value associated with the actual current flow, the current sensor being further operative to generate an analog signal indicative of the amount of actual current flow sensed in the at least one power line; an analog to digital converter coupled with the current sensor and operative to convert the analog signal to a digital representation of the amount of the actual current flow; an assumed voltage value of the at least one power line, wherein the assumed voltage value may be different than the actual voltage value, the assumed voltage comprising an approximation of the actual voltage value; and a processor coupled with the analog to digital converter and the assumed voltage value and operative to calculate at least one measure of power consumption by the electrical load based on the digital representation, the calculation being further based on the assumed voltage value instead of the actual voltage value.

The preferred embodiments further relate to a method of monitoring electrical energy consumed by an electrical load. In one embodiment, the method includes: sensing actual current flow in at least one power line which is supplying electrical energy to the load, the at least one power line being further characterized by an actual voltage value associated with the actual current flow; generating an analog signal indicative of the amount of actual current flow sensed in the at least one power line; converting the analog signal to a digital representation of the amount of the actual current flow; providing an assumed voltage value of the at least one power line, wherein the assumed voltage value may be different than the actual voltage value, the assumed voltage comprising an approximation of the actual voltage value; and calculating at least one measure of power consumption by the electrical load based on the digital representation, the calculating being further based on the assumed voltage value instead of the actual voltage value.

Further aspects and advantages of the invention are discussed below in conjunction with the preferred embodiments.

### BRIEF DESCRIPTION OF THE DRAWINGS

FIG. 1 depicts a block diagram of a commercial building incorporating the system of the present invention.

FIG. 2 depicts a block diagram of the internal circuitry of an example of an energy monitoring device of the present invention.

FIG. 3 depicts a block diagram of a first procedure retrieving a verified energy reading from the energy monitoring device of the present invention.

FIG. 4 depicts a block diagram of a second procedure retrieving a verified energy reading from the energy monitoring device of the present invention.

FIGS. 5-6 depict an exemplary method of mounting a monitoring device according to one embodiment.

FIGS. 7-8 depict exemplary commissioning reports according to one embodiment.

FIGS. 9A-9C depict an exemplary CT locking device.

FIG. 10 depicts exemplary voltage waveforms and time relationships for several possible current waveforms according to one embodiment.

FIG. 11 depicts an exemplary voltage displacement device for use with the disclosed embodiments.

FIG. 12 depicts a block diagram of an alternate commercial building incorporating the system of the present invention.

FIG. 13 depicts an exemplary process for using assumed data values in computations according to one embodiment.

### DETAILED DESCRIPTION OF THE PRESENTLY PREFERRED EMBODIMENTS

Herein, the phrase “coupled with” is defined to mean directly connected to or indirectly connected through one or more intermediate components. Such intermediate components may include both hardware and software based components. Further, to clarify the use in the pending claims and to hereby provide notice to the public, the phrases “at least one of <A>, <B>, . . . and <N>” or “at least one of <A>, <B>, . . . <N>, or combinations thereof” are defined by the Applicant in the broadest sense, superceding any other implied definitions herebefore or hereinafter unless expressly asserted by the Applicant to the contrary, to mean one or more elements selected from the group comprising A, B, . . . and N, that is to say, any combination of one or more of the elements A, B, . . . or N including any one element alone or in combination with one or more of the other elements which may also include, in combination, additional elements not listed.

In general herein, a public key is a number, formula, algorithm, function, etc. that is made, or intended to be, publicly available, i.e. made available to any user that wants it. A private key is a number, formula, algorithm, function, etc. that is intended to be kept private and is protected in some way from access. This protection may be in the form of secrecy, an enclosure, encryption, difficulty in access, etc. The more difficult it is to circumvent the protection, the better, however it will be appreciated that the utility of the disclosed examples is not dependent on the quality of the protection the private key.

An energy monitoring device that is designed to transmit its measurement values may not be accessible to be manually read by a person. This may be due to the fact that the energy monitoring device does not have a display or is otherwise physically inaccessible, and although the device may provide a communications pathway (wired or wireline) allowing it to be accessed by the energy provider, the device may not provide a direct communications pathway for the user. This causes a problem in that the user/consumer of the energy being monitored by the energy monitoring device may be left with no way of verifying that they are being billed accurately for the usage that their respective energy monitoring device is measuring. For instance, a configuration error may result in the user being billed based on an incorrect or mis-configured energy monitoring device or the user may simply not trust the energy provider to provide an accurate accounting of energy consumed.

The following description details various mechanisms for verifying the integrity of readings taken from electrical monitoring devices which are in communication with a central computer through a mesh network. It will be clear to those skilled in the art that the mechanisms defined herein are also applicable to monitoring other parameters indicative of energy consumption.

Public/private keys may be used for authenticating a message sent from one computer to another computer over communications pathways such as the Internet. In general, a message can be authenticated by performing a function (such as a hash) on the message data with a private key of one computer. A second computer can then verify the origin of the message by performing a corresponding function on the results of the first function and the message data using the first computer's public key.

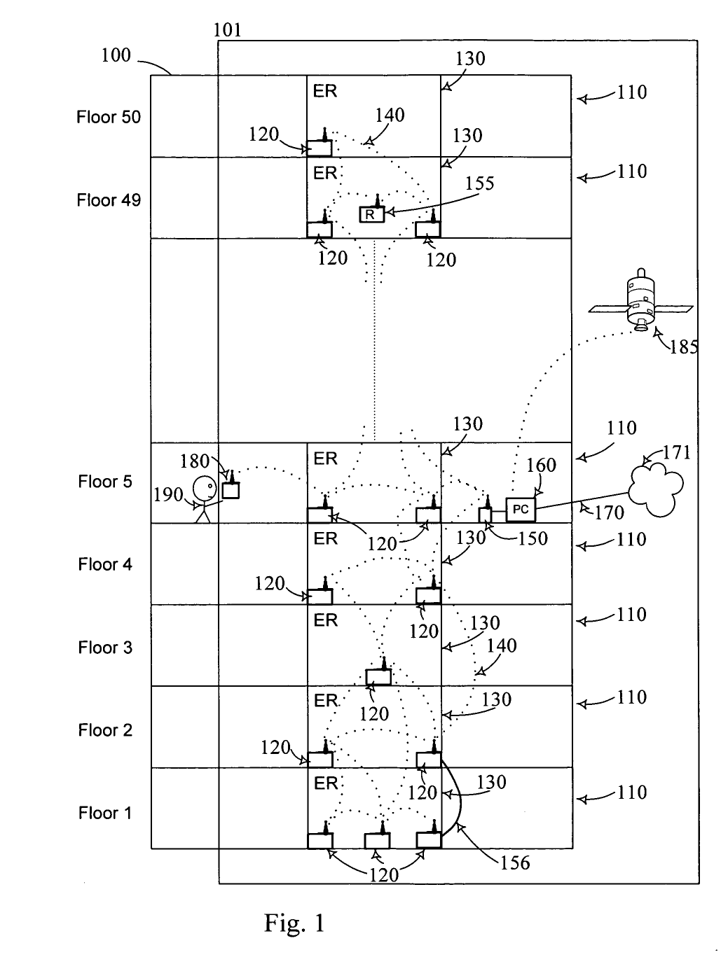

FIG. 1 depicts an exemplary commercial office building 100 for use with the disclosed embodiments. The commercial office building 100 has a number of floors 110. Each floor may contain an electrical room 130. Alternatively there may be more than one electrical room 130 per floor or only one electrical room 130 per a number of floors. Within each electrical room 130 there may be one or more energy monitoring devices 120 within an energy monitoring system 101. It will be appreciated that the location of the energy monitoring devices 120 is implementation dependent and that they need not be located in an electrical room 130. The energy monitoring devices 120 communicate among each other to form a mesh network, depicted in FIG. 1 by multiple communications links 140 shown between the energy monitoring devices 120. It will be appreciated that fewer or more communications links 140 may be used between monitoring devices 120 and that the availability of a communications link 140 between any two monitoring devices 120 may fluctuate depending upon conditions such as interference, etc. Repeaters 155 may also be provided to facilitate communications between two devices 120 which may not otherwise be able to communicate due to distance, interference, etc. Alternatively, one device 120 may have two antennas which operate at different power levels, gains, frequencies, modulation schemes, etc. to overcome interference, distance, etc. One of the antennas may be connected to a long cable (such as a coaxial cable) in order that the antenna may be located remotely from the device 120 in a more effective location for transmission/reception than the device 120. Alternatively, the architecture may provide a wireline segment 156 where communications between two devices are not possible otherwise. This may happen due to distance, interference, shielding, etc. The mesh network may use the wireline segment 156 in a similar fashion to the communication links 140. The wireline segment 156 may be implemented using power line carrier techniques over the office building 100 power lines or using standard wireline communications/networking architectures such as RS-485, RS-232, Ethernet, etc.

The device 120 may facilitate the replacement of its antennas such that for a given installation location, flexible, such as rubber encased or flexible wire, adjustable, directional, high gain, or different propagation pattern antennas may be substituted to facilitate more reliable communications. Further, antenna enhancing devices or devices which enhance RF transmission by utilizing proximate structural elements such as metal casings, glass windows, etc., may also be used

The mesh network also encompasses a gateway 150 which facilitates communications with a computer 160 or other computing device. The computer 160 may communicate energy data and other data over a LAN 170. The computer 160 and gateway 150 communicate over a serial or other form of communication link. Alternatively, the gateway 150 may interface with the LAN 170 directly and the computer 160 may be connected to the LAN 170 in a different part of the building 100 and communicate with the gateway 150 over the LAN 170. The computer 160 may receive a time reference from a GPS satellite 185. Alternatively, the GPS satellite 185 signal may be received by an energy monitoring device 120, gateway 150 or repeater 155 within the mesh network. In this alternate case, the time within the alternate device becomes the reference for the energy monitoring system 101. The LAN 170 may interface to a WAN 171 such as the Internet. The gateway 150 may, for example, be located in a chief engineer's office where a connection to the LAN 170 is readily available. There may be more than one gateway 150 in the energy monitoring system 101 facilitating extraction of data from the system at more than one point in the mesh network. The gateways 150 may communicate over the LAN 170 to a concentrator that aggregates information from all the gateways.

With present mesh networks it is often difficult to determine the health/status of the network. Typically, only basic information is available from any given node, such as the ability of the node to communicate with the gateway and the signal strength for closest node, both of which give no indication of redundant paths or communication error rates, or other more detailed status information. Often after a network is installed, unhealthy networks, e.g. network with one or faulty links or devices, are identified through missing data or low percentage of responses to requests. The need exists to have an easy low cost way to determine health/status of the network especially during installation of a system.

In one embodiment, a data aggregation device, which may be a portable communications device 180, or other device coupled with the mesh network such as the gateway 150 or computer 160, or software executing thereon, provides the ability to gather network status/statistical information from the mesh network via self/automated reporting by the devices which make up the network. Such self-reported data may include perceived signal strength, delivery delays, multiple or confusing responses, non-responsive or slow responding nodes, communications errors, etc. Further, this data may include both current and historical data collected over a period of time. Such reporting facilitates the identification of weak network links, failing nodes, redundant paths, etc. The reporting may also take place via the display or local communications connection of the particular device to allow a physically proximate user to assess and view the network status as perceived by that particular device. In an alternate embodiment, each device may report the status information of other devices as well, such as other nodes/devices which are proximate to the particular device. At the point of data aggregation, this reported data may be collected/aggregated and reported to a user to present an overall network status of the entire network, or a particular portion thereof, such as by a graphical presentation or the like which shows failing links, links with high error rates, low signal strength, etc. possibly using colors or other visual indicators.

In an alternate embodiment, rather than rely on a self reporting mechanism, or in addition thereto, diagnostic packets may be sent or requested from each node over the wireless link containing data used by the gateway to identify weak or failing links or nodes in the radio network. The diagnostic packets may contain such information as signal strength of all neighboring nodes in priority of use and number of redundant paths. This data would then be used by the gateway to determine if additional repeaters are needed in specific locations. In one embodiment, diagnostic packets are capable of being directed over particular network paths of the mesh network to focus diagnostic activity on particular areas of the network.

Where weak links or troublesome nodes are discovered, measures could be taken to increase communication reliability. For nodes that have weak links to the rest of mesh network, for example communications may be attempted more often in an effort to effectively increase the chances that some of the communications will get through during periods of reliable connectivity and causing the mesh network to seek better links with this device.

Many issues with mesh networks occur upon installation of the network and may be resolved at that time, prior to actual use and reliance on the network. For example, during the installation of a large number of meters, such as can be found on a commercial building meter installation (typically 100 meters or more), a fairly high probability exists that one or more of the devices will be installed incorrectly. Furthermore, some devices may have limited error detection capability due to limitations in their memory capacity/code space and are only be able to detect simple and obvious errors. Typical errors which simpler devices typically detect include: wrong phase connections, reversed CT connection or bad CT and phase connections (open/shorted).

In one embodiment, the capability to generate an automated commissioning report from the different devices is provided. The commissioning report is generated by first obtaining assorted real time device data from all of the operating devices and then analyzing the real time values for validity. The real time device data may include RMS current and voltage readings, frequency, apparent (VA) power, real (W) power and reactive (VAR) power and power factor. Using a combination of these values, in conjunction with the measuring mode (delta or wye), angles can be determined between voltage and current phases. For example, if the real power is negative and in the installation it is known to be positive, i.e. since power is being delivered, this may indicate that the current transformer (“CT”) could be reversed. For devices that can automatically compensate for a reversed CT, a warning would be provided indicating that the CT phase is reversed.

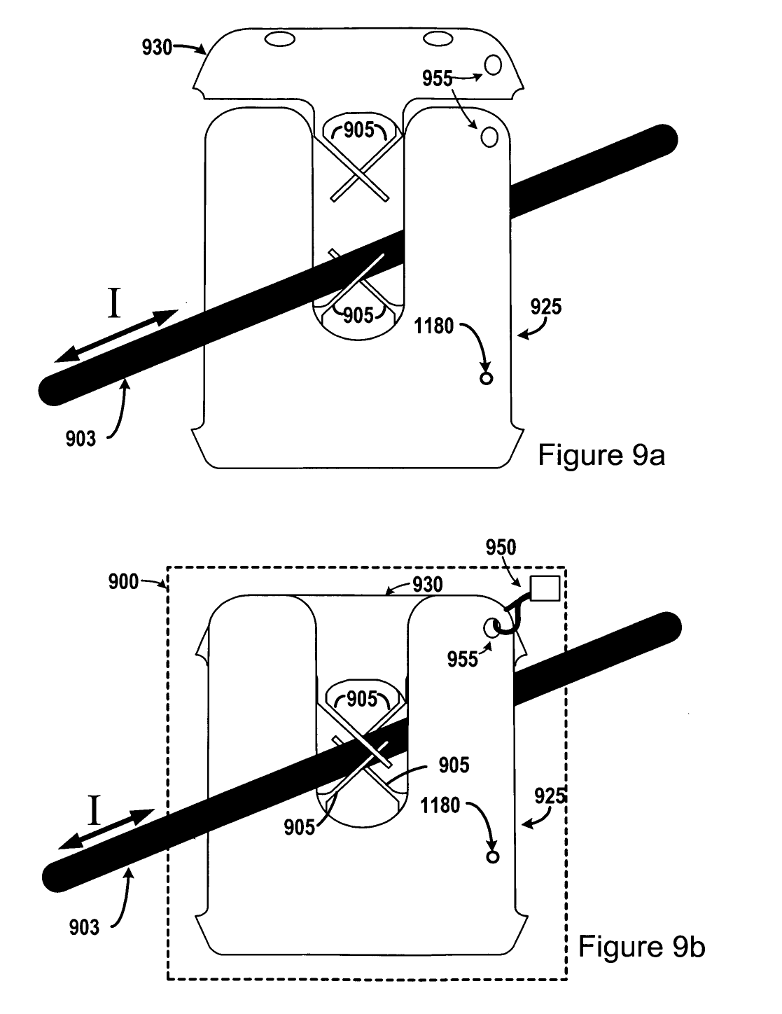

In this embodiment, every device in the installation is automatically interrogated when the device is initially detected in order to provide an entry for the commissioning report. Expert system software is provided at the point of data aggregation which uses common sense relationships to analyze the data and determine if the readings are reasonable. The installer will go over the commissioning report and evaluate each error or warning for validity. For example, if voltage and current from I2 are reported to be zero on a floor/panel, and the installer knows there are no loads on the circuit, then the reading is reasonable. However if there is expected to be a reading, then there is something wrong with the CT, connections or configuration and the installer can take corrective action. An exemplary table based commissioning report is shown in FIG. 7.

The commissioning report may be further enhanced by providing relative phase angles between all the current and voltage phases. This information may be provided by a device such as the ION 6100 power meter, manufactured by Power Measurement, Ltd., located in Saanichton, British Columbia, Canada. Using the phase angles, swapped current or voltage phases may be easily determined. To simplify the presentation, the commissioning report may simply provide a vector diagram (as found on ION 7500 power meter, also manufactured by Power Measurement, Ltd.) for each device with an appropriate OK, WARNING or ERROR message. This would reduce the clutter of a large number of real time reading values. FIG. 8 shows an exemplary vector based commissioning report.

The installation of mesh networks using monitoring devices, such as the ION 6100 mesh network based power meter, can be complicated by intermittent network connections due to marginal transmission and reception of data over the network. Typically, during the commissioning of the system, all that can normally be done is to verify that each device in the network communicates with a central gateway. This verification simply tells the installer that the system is currently working properly, but it does not tell how much operating margin the radios have. For low cost devices, it is usually not feasible to include measurement of signal strength.

The operating conditions of a mesh network radio can change due to near body effects, temperature, interference, fading and multi-path, etc. If node reception, i.e. signal strength or connection quality, is close to the operating limit of the radio, then small changes of the operating conditions may render a node non-communicating.

In one embodiment, the use of a variable power mesh network node is provided to validate the correct operation of the system at a reduced power level. During commissioning, the system is switched to a lower power mode which operates the radios at a lower power level than the radios are normally capable of. Once the system has been verified to be fully operational (which may require the installation of appropriate routers to complete the network), the system is switched to the normal operating mode at the normal radio power. During normal operation, the mesh network node power will be increased to a higher (normal) power level assuring that the reception and transmission of mesh network data is well above any marginal radio operating parameter.

In yet another embodiment, the monitoring devices feature the capability to be located a inside or proximate to a circuit breaker with the monitoring device's current transducers being coupled with the breaker's loads and sending data to the monitoring device/meter. The current transducers also feature mesh network capability, i.e. RF communications capabilities as described herein, and communications between the device/meter and the current transducers is accomplished via a mesh communications network or other medium. In this embodiment, the device/meter is physically configured to fit within a particular form-factor of the breaker panel.

In yet another embodiment, the mesh network may include nodes mounted to elevators, or other moving mechanical systems, and utilizing the movement of the elevator to bring the elevator-mounted node within a communications-proximity to portions of the mesh network which are otherwise inaccessible. The elevator mounted node may act as a store and forward device facilitating communications between other network devices as connections are established and lost due to its movement. The elevator mounted node may store data from particular devices until the elevator moves to another location where forwarding of the data is possible or alternatively, the elevator mounted node may use alternate communications means such as higher power RF or wireline communications to forward the data.

In yet another embodiment, the mesh network of monitoring devices further include a capability to share common area usage charges based on actual or more closely approximated usage of common areas. The monitoring devices or central aggregation device may feature the capability to discern usage of common areas by particular tenants, or at least make approximations of such usage. Where reasonable approximations of particular tenant usage may be determined and associated with particular consumption, that consumption may be appropriately charged to the particular tenant. For example, power consumption by the elevators may be apportioned to tenants by the floors which they occupy such that a tenant which occupies multiple floors or is a frequent elevator user is apportioned a more appropriate amount of the charges associated with operating the elevators. Other methods of approximating particular tenant usage of common areas may rely on building access identifications cards and their use at particular access points throughout the facility or RF enabled identification badges which permit tracking of tenant movement throughout the facility. Further, temperature sensors, or other coupling with environmental control systems, may be provided to measure HVAC usage in particular areas to properly apportion those costs.

A user 190 may transport a portable communication device 180 around the building 100. This portable communication device 180 may be used to read energy registers from the various energy monitoring devices. The portable communication device 180 and the energy monitoring device 120 may both have indicators (such as LEDs) on them that light, or otherwise signal, when communication is established between the two devices. This indicates to the user that they are in communication with the correct energy monitoring device 120. In addition, the portable communication device 180 may read a secondary register from the energy monitoring device 120 which is a hash of the energy registers and a pattern such as the private key of the energy monitoring device 120. If the pattern is known only to the energy monitoring device and a system such as a billing system within a utility, the registers within the portable communication device will be difficult to tamper with without detection. The secondary register may appear to the user of the portable communication device 180 as just another register such that the user is not aware that the secondary register may be used for tamper detection. The portable communication device 180 may be a handheld meter reader.

In one embodiment, a handheld device is provided for performing network/device related tasks, such as optimizing monitoring device (or antenna) locations for optimal communication performance, performing routine monitoring of network status, determining or monitoring for specific device availability or activity, determining device locations (by proximity or by using GPS capabilities), communicating with devices via the mesh network and/or direct/local device interfaces, such as for setting up/initializing devices, and acting as a mesh enabled data display.

When installing wireless meters/nodes it may be advantageous for the electrician or commissioning engineer to have a separate handheld radio that is used to determine suitable positioning of the devices being installed. The handheld radio would be able to communicate with the network being installed and have a faster rate of communication with the gateway 150. The rate of communication with the gateway 150 could be configurable to suit all sizes of networks. The handheld radio may have a display or some other user interface such as LED's to help determine radio link quality into the network.

Alternatively each device being installed could have a deployment mode where its rate of communication to the gateway 150 would be faster for a period of time, thereby giving the installer more feedback as to the success and quality of the installation. The device could have a button that is used to activate the deployment mode for this period of time. The installer would then be able to move the device around until a suitable position is found, with the device and/or gateway determining and reporting the status of the communications link at a more frequent rate than might be had in the normal operating mode. The installer would be aware of a suitable position through data reported by the device, such as via LED's or the display on device. Deployment mode may only last for a period of time that is sufficient to find acceptable location and communicate with the network. The deployment mode may automatically shut off to prevent installed devices being left in deployment mode.

In both of the cases above the network would have to be installed as follows:

The gateway 150 is installed.

1. Devices can then be installed from the gateway 150 out so that as each device is installed, they are able to communicate with the gateway 150; and

2. If it is not possible to install the devices, then temporary repeaters are put in place of where devices or repeaters will have to be installed to complete the network.

Alternatively, the gateway 150 may have a deployment mode where statistics are gathered for each node in the network. The gateway may perform ping statistics on nodes, request diagnostic packets containing such things as signal strength, # of hops etc. After meters are installed, the gateway would then have to be taken out of deployment mode to gather energy information.

Locating installed devices may prove to be difficult especially if a meter is installed in a location different than the intended location. To assist in locating devices each meter could be outfitted with GPS chips. The location of the device could then be reported through the wireless link. A handheld GPS unit could then be used to assist in locating the device.

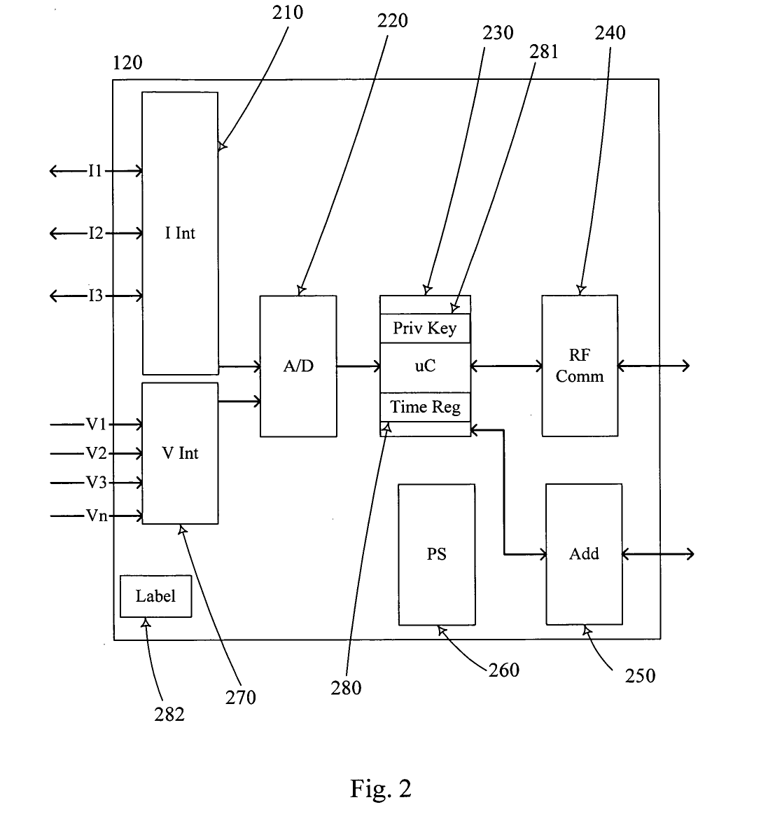

FIG. 2 shows a block diagram of an energy monitoring device 120 according to one embodiment. The energy monitoring device 120 includes electrical current interface circuitry 210 and electrical voltage interface circuitry 270. The electrical current interface circuitry 210 and electrical voltage interface circuitry 270 are operative to interface with power conductors which supply electrical energy to a certain load or area of the building 100. This interface may be direct or through appropriate current or voltage transformers. In alternative embodiments, the energy monitoring device may lack either the electrical current or electrical voltage interfaces 210, 270 depending upon the implementation and monitoring requirements of the device 120. The energy monitoring device 120 further includes an analog to digital converter 220, a micro-controller 230 coupled with the analog to digital converter 220, and RF communications circuitry 240 coupled with the micro-controller 230. The electrical current interface circuitry 210 and electrical voltage interface circuitry 270 scale the signals from the power conductors to voltage levels compatible with the analog to digital converter 220. The analog to digital converter 220 provides digital representations of the voltage and current in the power conductors to microcontroller 230. Using these signals, the microcontroller 230 calculates at least one power parameter such as kWh, kVAh, kVARh, kW demand, kVA demand, kVAR demand, etc. The microcontroller 230 transmits this power parameter through RF communications circuitry 240 through the mesh network and gateway 150 to computer 160. The computer 150 may send configuration and command data (such as demand reset) to the energy monitoring devices 120 through the mesh network. The microcontroller 230 also maintains time for the energy monitoring device 100 in a memory register 280 which may be internal to and/or external to the microcontroller 230. The microcontroller 230 also maintains a private key 281 in internal and/or external memory. The energy monitoring device 100 also contains a power supply 260 which may interface to the same voltage signals as the voltage interface circuitry 270 or to an alternative power source. The power supply 260 may incorporate a battery or capacitor to facilitate operation when operating power is lost. The power supply 260 may also incorporate crystal radio type circuitry as an alternate source of operating power such that RF power present from local AM radio stations may be utilized to power the energy monitoring device 120. Additional circuitry 250, such as wireline communications, I/O circuitry, etc. may also be provided in the energy monitoring device 120. A label 282 is provided on the outside of the energy monitoring device 120. The label may provide the public key corresponding to the private key 281. Alternatively, the public key may be shown on a display coupled to the microcontroller 230 or periodically broadcast over the communications links 140 forming the mesh network, either automatically or in response to a request. In one embodiment, the public key and associated private key may be periodically changed by the microcontroller 230. The microcontroller 230, may use A/D 220 readings, RF noise readings, etc. as random numbers to generate these public/private key pairs or, alternatively, the key pairs may be inserted during manufacture or may be input to the energy monitoring device 120 using other methods.

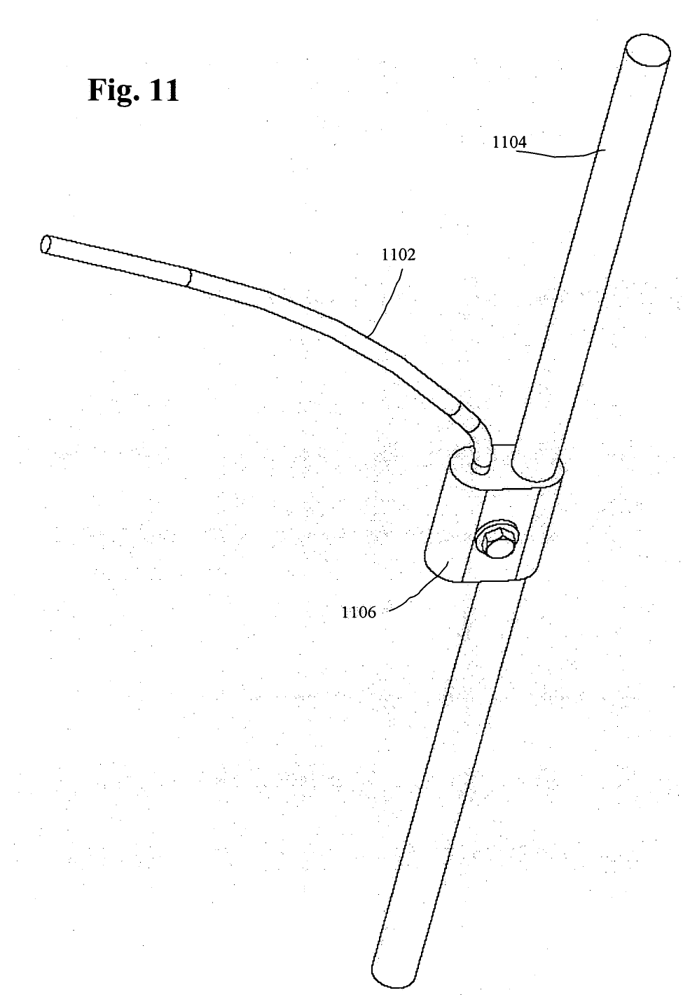

In one embodiment, a voltage displacement device is utilized to allow any piece of monitoring equipment to be connected to a voltage conductor without the need to power down the line to be monitored. This piece of equipment could be an integral part of the monitoring devices voltage leads or a separate device that would allow for a galvanic connection between the voltage source and the monitoring device. An exemplary voltage displacement device 1102 is shown in FIG. 11 attached to a power line 1104. The voltage displacement device 1102 pierces the power conductor 1104, in a safe and insulated manner, to provide a means of powering the monitoring device as well as providing a signal to monitor and/or measure. The device 1102 is clamped and locked to the power conductor 1104 utilizing a locking/clamping mechanism 1106 in a manner that would require a tool for removal, thereby preventing unauthorized persons from tampering or removing the connection. Even when local electrical codes, procedures and/or standards require powering down a conductor before adding a connection to it, the voltage displacement device may save installation time and cost since no splicing, terminal connections, etc. are necessary to make the connection.

In one embodiment, a power meter is provided which includes multiple radios for redundant operation in case of a failure or to facilitate communications over multiple RF channels simultaneously. Alternatively, a low power and a high power radio, possibly similar to the low/high power radio described above for device installation, may be provided, wherein the device determines the optimum radio to use based on ambient environmental conditions, time of day or other trigger.

If, for some reason, nodes in the main radio network stop communicating energy/power data there may be an alternate method to extract data manually or through some other low cost method. Due to the nature of mesh networks if nodes in the middle of the network lose power, all nodes that communicate through those nodes may also stop communicating. Using a point to point radio technology would enable a person to go from floor to floor collecting energy/power data from the non-communicating devices until the mesh wireless network problem is resolved. In particular the second radio technology could be Bluetooth, 802.11x (a, b or g), infrared, or similar networking technology, so that the data collector could use a handheld device to communicate with a single device if the address is known (point-to-point).

In one embodiment, the gateway device 150 may provide a firewall capability, or this capability may provided by a separate device logically located so as to be able to control and contain network traffic, which prevents unauthorized access to the mesh network from an external network, such as via the gateway device. The firewall device may further permit limited unauthenticated wireless access or limit access based on the level of security or level of trust in a given entity or method of access.

Often in establishments, the department responsible for internal networks will be wary of attaching devices to their internal network. However, this department may be receptive to providing a network connection to a demilitarized zone or directly to the internet. In this case the firewall within or coupled to the gateway protects the gateway 150 and mesh network devices from unauthorized access. The gateway may report to the computer (which may be within the corporate network) through protocols such as SMTP, HTTP, etc. which most corporate firewalls do not block.

Often there is no Ethernet connection where the gateway is to be installed. Instead of running a wired connection to the demilitarized zone, a secure wireless technology such as WI-FI may be used.

In yet another alternative embodiment, the capability for a monitoring device or other node to act as a gateway for legacy devices, which do not feature the capability to communicate via the mesh network, is provided. The gateway-enabled device may act as a simple conduit allowing bi-directional communications with the legacy device as if the legacy device were itself on the network. This may be accomplished via protocol encapsulation. Alternatively, the gateway-enabled device may act as a master device, server or other intermediary which mediates communications between the network and the legacy device(s). For example, the gateway-enabled device may aggregate data retrieved from multiple legacy devices and pass the aggregate onto the network.

In RF challenged zones, i.e. where RF based communications are difficult, or for supporting legacy devices, it may be desirable to communicate to meters via the RS485 serial bus. In one embodiment, a gateway device is provided that supports both wireless technology and multiple/single RS485 connections for legacy devices or in areas were wireless does not work. The gateway device, as described, may act as a single data collector for multiple nodes communicating via RS485 and wireless links. The gateway device may be an application specific device for bridging other devices onto the mesh network or may be an additional function provided by a mesh network node, such as the monitoring device described above.

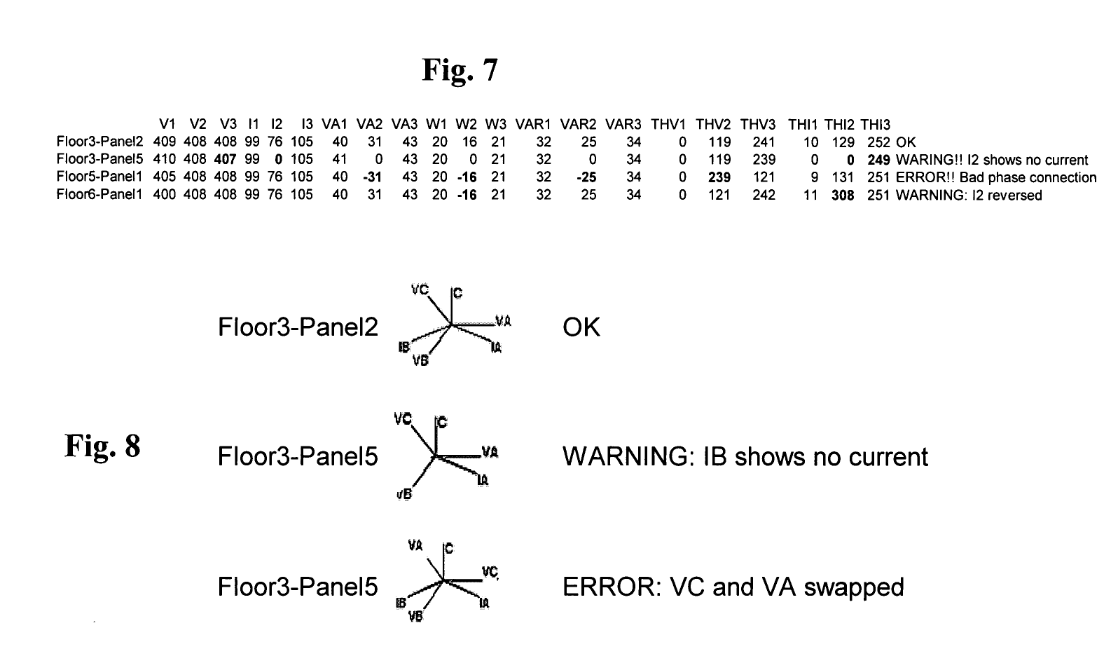

In yet another embodiment, a monitoring device or other node device is provided with flexible power options allowing it to draw operating power from various sources, without interfering with those power sources. This adds to the flexibility of the device to be placed in locations which may not have convenient sources of operating power, the sources of operating power may not be reliable or stable, and/or the sources of operating power are the same as that being monitored and isolation of the device is desirable. Such sources of electrical power may include emergency power sources such as power for exit or emergency lighting systems, solar power (via a window or ambient lighting), telephone system power, battery power, RF power (similar to the operation of Radio Frequency Identification Devices (“RFID”) or crystal radio sets) or combinations thereof. In this way, there is reasonable assurance that the device will receive a constant uninterrupted supply of operating power. Such devices may be further provided with flexible mounting options such as the ability to be mounted to a light bulb socket or wall socket/outlet. The ability to lock the device in place and draw operating power therefrom may also be provided. An example repeater 155 that may be plugged into a wall 506 outlet 502 having one or more power sockets 504 is shown in FIGS. 5 and 6. The repeater features an antenna 508 and power connectors 510. In this configuration, the repeater 155 draws power from at least one of the sockets 504 and is secured in place with a replacement screw 514 for the wall outlet 502. The repeater 155 can thus not easily be removed either accidentally or intentionally. The screw 514 may incorporate a one-directional drive engagement to further discourage removal. The repeater 155 may also provide pass through outlets 512 such that the outlet 502 can still be used. In an embodiment which fits into a light socket, a pass through socket may be provided to allow the socket to be used for illumination purposes.

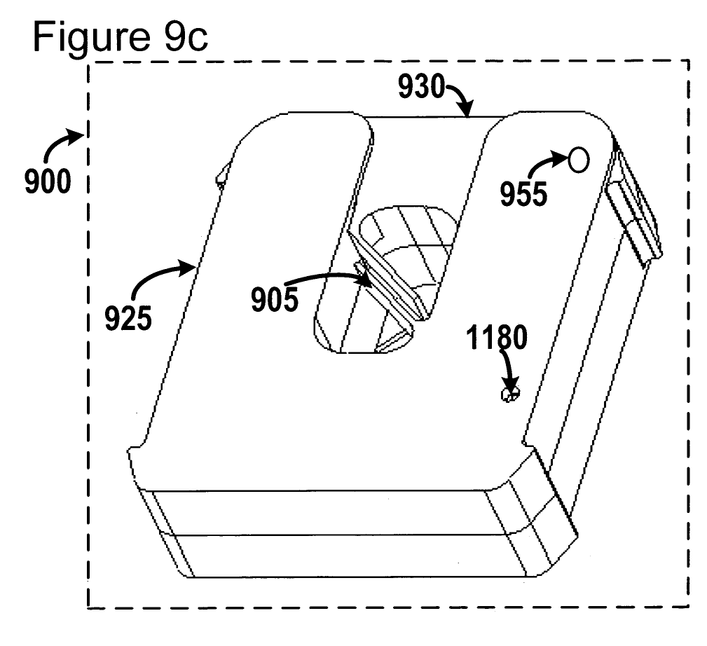

In one embodiment, mesh network enabled current transducers or transformers (“CT's”) include a physical security mechanism to prevent or indicate tampering and/or removal of the CT from the power line being monitored. FIGS. 9A-9C depicts an exemplary CT 900 having a revenue lock mechanism 955. Effectively, the CT includes two interlocking portions 925 930, each of which come together to encircle the power line 903 to measure the current passing there-through. The interlocking portions 925 930 each feature a locking hole 955. The locking holes 955 of each portion come into alignment when the portions 925 930 are assembled around the power line 903 thereby allowing a sealing device 950, such as a lock or locking wire, to be fed through both holes 955 preventing removal of the CT without breaking the locking mechanism 950 and/or causing indication of tampering.

In yet another alternative embodiment, the capability to update and/or modify the firmware of a monitoring device or other mesh network node via a mesh network is provided. In operation, the particular monitoring device(s) or other mesh network node(s) to be upgrade/modified may be instructed to enter an upgrade/modify mode. Upgraded or modified software/firmware may then be transmitted via the network to the device as one or more packets. The device(s) receives and assembles these packets into a memory, re-requesting packets that are received with errors and determining and re-requesting missing packets. Once the new code has been fully transferred, the device is instructed to begin executing the new code. Prior to executing the new code, the device may validate or otherwise authenticate the code and may further perform functions to ensure that the device can recover should an error occur, such as by performing a data backup operation. In an alternate embodiment, the special upgrade mode is unnecessary. In this case, the packets of new code contain an indicator to the device as such. When the device sees such packets, it writes them to its memory store and assembles the complete code, re-requesting errant packets and tracking and re-requesting missing packets. Once all of the packets have been received, as determined by an indicator which tells the device how many were to be received or by an packet denoted as the last packet sent, the device automatically switches over to the new code. Prior to switching over to the new code, the device may validate the new code, or otherwise perform an authentication. Further, the device may perform a backup operation of any stored data to ensure that recovery is possible if an error occurs.

In one embodiment, a monitoring device is provided which is capable of utilizing assumed voltage readings in situations where it is not possible to determine actual voltage readings from the circuit being monitored. This capability allows the monitoring device to operate until it becomes possible to connect it to the voltage terminals of the circuit to be monitored, or operate indefinitely without connection to the voltage terminals, depending upon the application. When installing the energy monitoring device 120, it is often necessary to power down the circuit to be monitored so that voltage connections can be made to the energy monitoring device. Otherwise, the installer may be exposed to hazardous voltages and/or the device 120 may experience an unexpected power surge on its inputs upon connection, thereby damaging the device. However, installation of the current connections can often be accomplished with the circuit energized when using non-contact sensors, such as “clamp-on” CTs which rely on induced current flow, as the risk of injury or damage is lessened.

Therefore, the energy monitoring device 120 according to the present embodiment provides the ability to estimate power and/or energy readings when only the current inputs are connected. As described, this estimated-operation may be used on a temporary or permanent basis. If used on a permanent basis, the energy monitoring device 120 may be provided without voltage inputs so as to lower manufacturing costs. This may occur, for example, where the application demands may be met using assumed voltage values and, accordingly, the user does not wish to pay for or install fully functional devices 120.

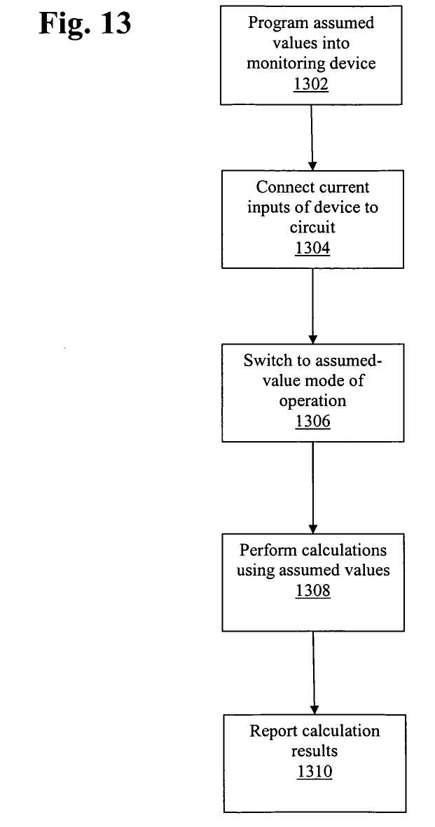

In order to estimate power and/or energy readings, several techniques may be used. In one embodiment shown in FIG. 13, the energy monitoring device 120 may be programmed with an assumed voltage and/or power factor based on the particular load it is monitoring (1302). The device 120 may be programmed prior to, or after, connecting the current inputs to the circuit to be monitored (1304). The assumed value(s) is/are stored in a memory within the device and used by the processor as the basis for computing other data regarding the monitored circuit, as will be described. Programming assumed values into the device 120 may be accomplished directly using direct communications inputs provided by the device 120 or through the mesh network or other network communications input. Once programmed, the device switches into an assumed-value mode of operation, either manually or automatically, as described above (1306). The assumed voltage and/or power factor values may then be utilized by the device 120 to perform the requisite power and/or energy calculations (1308). The computed results may then be reported as per the normal operation of the device 120 (1310). As noted above, the reported results may include an indicator which indicates that the calculations were based on assumed values and may further indicate a margin of error as such. In an alternate embodiment, multiple power factors, for different load currents, are provided and the energy monitoring device 120 interpolates between these power factors based on the current present in the circuit being monitored. For example, the energy monitoring device 120 may be provided with an assumed voltage of 480VAC, and an assumed power factor of 0.84 at full load current (e.g. 40 Amps), an assumed power factor of 0.8 at ¾ load current and an assumed power factor of 0.72 at ½ load current. The energy monitoring device 120 may then interpolate the power factor to provide interpolated values for use in power and/or energy calculations based on actual current values which may range between the programmed assumed values or outside of them.

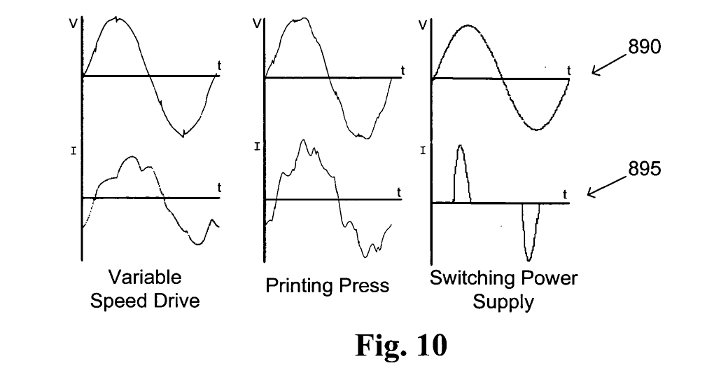

Alternatively, the energy monitoring device 120 may be programmed with an assumed voltage waveform and time relationship to the actual waveform representative of the actual current present in the circuit being monitored. FIG. 10 shows several example voltage waveforms and time relationships 890 for several possible current waveforms 895. The energy monitoring device may use techniques such as fuzzy logic, artificial intelligence, point by point comparison, etc. to determine the closest match current waveform in a stored suite of waveforms and then use the corresponding voltage waveform including the assumed phase or time relationship to the current waveform in power and/or energy calculations. In yet another alternative embodiment, an assumed voltage magnitude may be programmed into the energy monitoring device 120 over the mesh network or the energy monitoring device 120 may be manufactured for a given voltage. This voltage magnitude may then be applied to the assumed voltage waveform during the calculation of power and/or energy (ie., each point in the assumed voltage waveform may be multiplied by a constant such that the rms value of the voltage waveform used in the power/energy calculations is the same as the voltage magnitude provided).

Further, when the monitoring device 120 is operating using assumed voltage data, an indicator may be appended to all calculation results to indicate to a user or a data aggregation system that the data that the monitoring device 120 is producing is based on assumed values. Further, a visual indicator on the monitoring device 120 itself may indicate such operation as well.

In one embodiment, the assumed values are stored in a memory within the device 120 and referenced by the device 120 for performing calculations as described when the device 120 is placed in a “assumed voltage” mode of operation, either automatically or manually by a user via the device's 120 user interface or remotely over a network. This mode of operation may automatically be activated when the device 120 is suitably programmed with assumed data values and the device receives inputs on its current inputs but not on its voltage inputs, such as when the voltage inputs are not connected or the inputs or connections to the circuit fail or otherwise become disconnected. Further, the assumed values may be stored as digital values which bypass the device's 120 analog to digital converter to be directly input into the processor of the device 120 or the assumed values may be stored in an analog form and act as pseudo inputs to the analog to digital converter when actual voltage measurements are not present. In one alternative embodiment, assumed voltage values are input into the monitoring device 120 by attaching a dummy voltage generator to the voltage inputs of the device 120 to feed an assumed voltage value to the device 120. This has the advantage of allowing the use of assumed voltage values on older devices 120 which lack the capability to be programmed to do so.

In addition to using the steady state current waveform to determine an appropriate voltage waveform and/or phase relationship to assume, the energy monitoring device 120 may analyze current waveforms during startup conditions, transients, surges or sags in current level to determine the type(s) of loads that are being powered. Assumed steady state voltage waveforms/phase relationships may be selected based on these conditions only or in combination with steady state current readings.

Several procedures for retrieving energy related data from energy monitoring devices 120 in the building 100 will now be discussed. It will be appreciated that the described procedures may be used alone or in combination without departing from the spirit and scope of the invention.

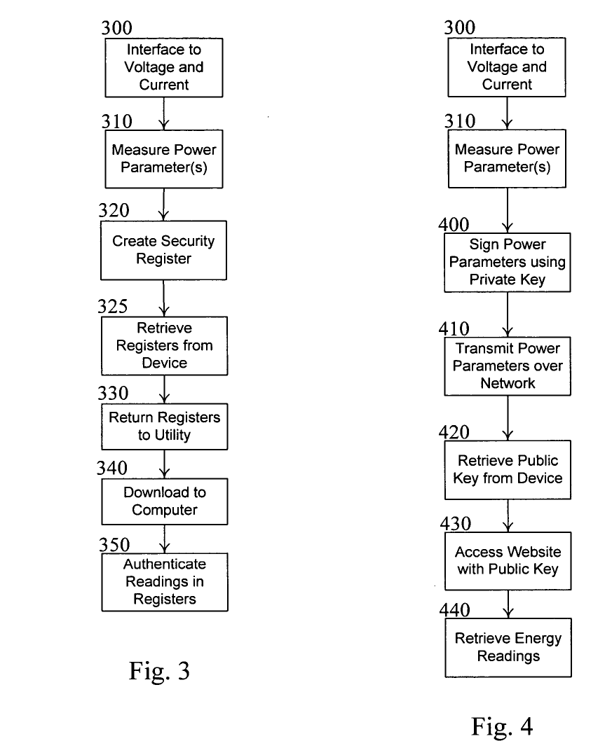

FIG. 3 shows a first procedure for retrieving energy related data from an energy monitoring device 120. The energy monitoring device 120 may be installed and interfaced to voltage and current signals (block 300) in order to monitor or measure at least one power parameter (block 310). The power parameter may be kWh, kVAh, kVARh, kW demand, kVAR demand, kVA demand, voltage, current, etc. The energy monitoring device contains a number of registers which store various measured and computed data values. This installation may be in electrical room 130 or any other appropriate installation location. The energy monitoring device creates a security register data (block 320) and stores this data in a security register in the device 120. This security register data is created by the operation of the private key 281 on the measured power parameter(s), for example, the private key 281 may be hashed together with the measured power parameter(s). The private key 281 may be any of the pieces of information described above. The register (including the security register) contents are then retrieved from the energy monitoring device 120 (block 325). The registers may be retrieved using any appropriate method. Some example methods include reading with a portable computing device 180 over a wireless link, manual recording on paper or into a handheld device or direct communication over a communication link to a central computer. The retrieved register contents are then returned to the utility or other entity that bills for energy usage (block 330). This may be accomplished by returning the paper or portable computing device 180, or storage media therefrom, to the utility or receiving the register contents over a communications link at the utility. The register contents, including the security register data from the security register, are then downloaded into a computer (block 340) where the register contents are authenticated using an appropriate public key (block 350) or using a shared private key. The public key may be any of the pieces of information described above.

Using this procedure, the possibility of an individual (such as a meter reader) tampering with energy readings is reduced due to the fact that the individual would either have to know the private key of the device, or be able to compromise the particular public/private key algorithm used in order to change the energy readings without detection.

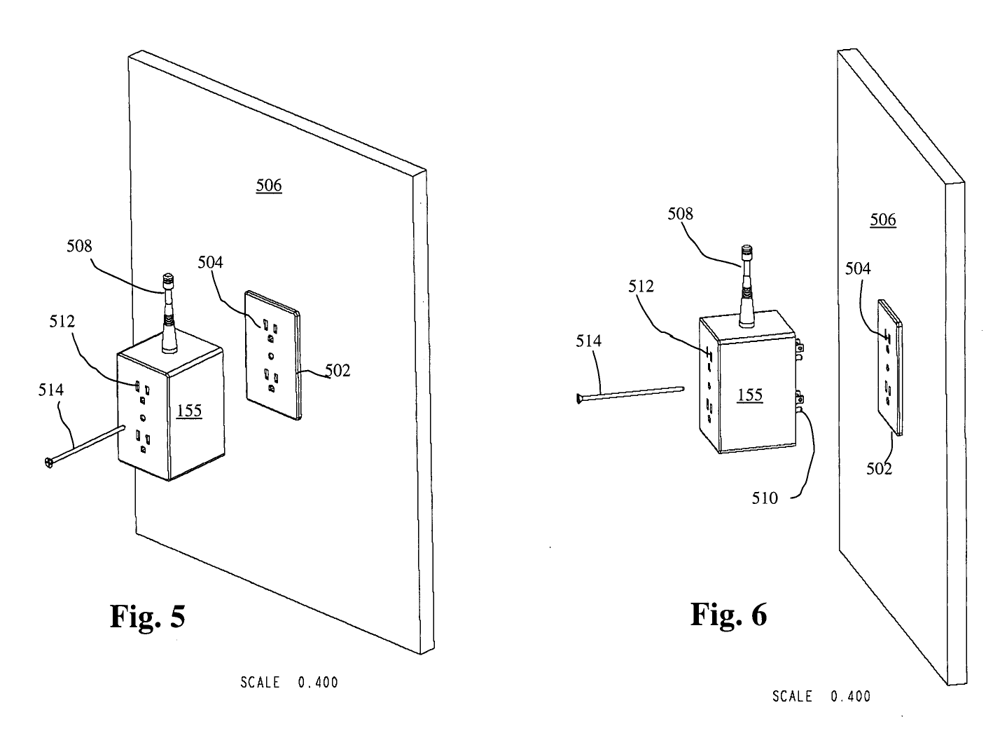

FIG. 4 shows a second procedure for retrieving power parameters from an energy monitoring device 120. This procedure may be appropriate for use when a consumer of energy wishes to verify that they are being billed correctly for energy usage. The energy monitoring device is installed and monitors at least one power parameter (blocks 300, 310) in a similar fashion as described in the previous procedure. The energy monitoring device 120 signs the power parameter(s) (block 400) utilizing a digital signature and transmits the power parameter(s) and signature over the network (block 410). As used herein, to “sign”, or alternatively, “digitally sign”, a message/document means to generate or otherwise append a “digital signature” to the message/document. A digital signature is an electronic signature appended to a message/document that can be used to authenticate the identity of the sender of a message/document, the signer of a document/message, ensure that the original content of the message/document that has been sent is unchanged and/or prevent repudiation of the document's/message's contents by the sender. The signed document/message, with or without the digital signature may, but need not, be encrypted, either before or after signing. A digital signature is typically generated based on the contents of the document/message and the sender's private key of the public/private key pair. Upon receipt, the receiver of the message “authenticates” the message contents using the sender's public key. The network may be the mesh network previously described wherein the packets are transmitted via other energy monitoring devices or any other appropriate communications means. This information is received by a computer which makes the information available to a consumer of energy (or other entity that wishes to verify energy readings). For example, the information may be made available by way of a website hosted on an appropriate server. The consumer of energy (or other entity that wishes to verify energy readings) retrieves a public key from the device (block 420). This public key may be on a label 282 or may be provided by any other appropriate mechanism as described above. The user may then use the public key to authenticate the information on the website (block 430) and retrieve the authenticated energy readings (block 440).

In order to secure packets transmitted between them, the energy monitoring devices 120 may use a shared key. In this example, before sending a packet to the next energy monitoring device 120, the originating energy monitoring device 120 encrypts the packet (or portion thereof) with the shared key. The receiving energy monitoring device 120 then decrypts the packet (or portion thereof) and only forwards the packet on to the next energy monitoring device 120 if the decryption process results in valid information. In this way, energy monitoring devices 120 or rogue devices may not insert themselves into the mesh network unless they know the shared key (or defeat the encryption/decryption algorithm).

The energy monitoring devices 120 may incorporate a GPS receiver or other mechanism for determining position (such as RF triangulation techniques). The position of each energy monitoring device 120 may be incorporated and secured in packets transmitted from the energy monitoring device using techniques such as those previously described. Any receiving device may then ignore data from a device that is not in an expected geographical location. This information may also be used to detect tampering such as for instance an energy monitoring device 120 being moved from its expected location. In addition, the portable communication device 180 may also incorporate a GPS receiver. The portable communication device may then compare its position to that of the energy monitoring device it is querying in order to verify it is querying the correct meter. This comparison may also be performed later after the data from the portable communication device 180 has been transferred to a computer.

At least one of the energy monitoring devices 120 may use pattern recognition or other techniques to scan packets they are forwarding to additional energy monitoring devices 120. These techniques may be used to detect rogue packets or packets containing malicious code. This may help prevent tampering with the system and may help prevent viruses from propagating through the system.

A mesh network provides redundancy in communications between devices. For enhanced reliability of the network it is desirable to have more than once communications path from each device. The computer 160 of the present invention may receive diagnostic information from the devices in the mesh network such that identification of devices with only one communications path leading from them may be identified to the user. Additional repeaters 155, gateways 150 or energy monitoring devices 120 may then be added to the system to improve reliability.

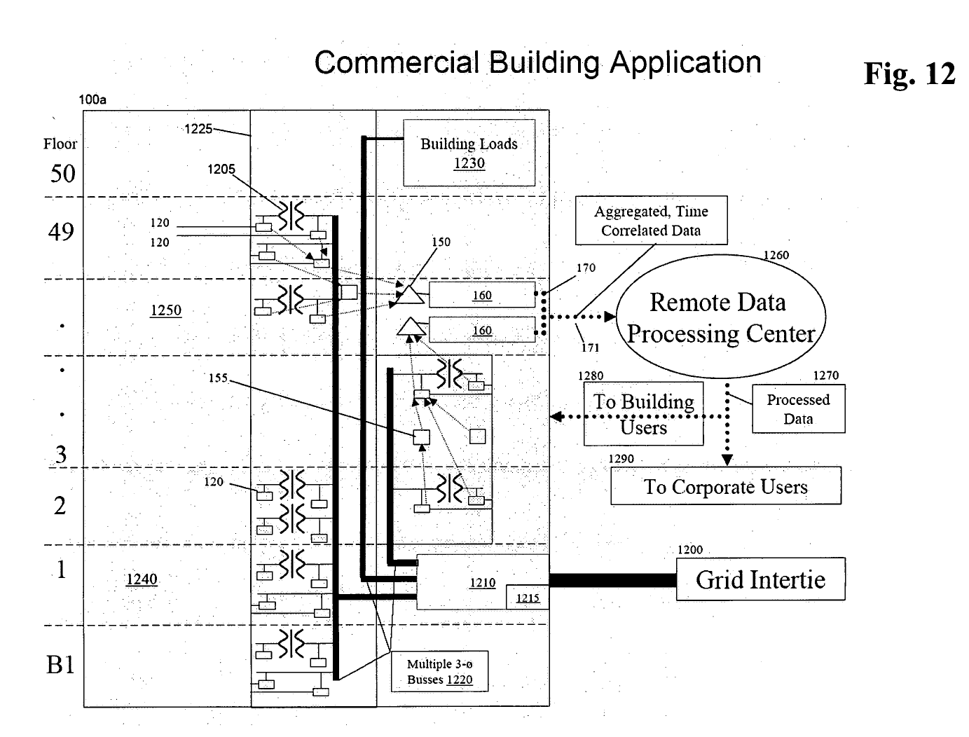

FIG. 12 shows an alternative exemplary commercial office building 100a for use with the disclosed embodiments. The office building 10a receives main power from a grid intertie 1200 which interconnects the building's 100a internal power distribution network with the utility's power distribution grid. A service entrance infrastructure 1210 couples to the grid intertie and provides multiple 3 phase buses 1220 for powering various loads in the office building 100a. In typical installation, only one energy meter is provided in the building to measure power parameters of power flow from the grid intertie 1200 to the service entrance infrastructure 1210.

Subsequent to the service entrance metering, power is distributed inside the building through various vertical shafts either with traditional conductors (older buildings) or via bus ducts (newer installations). The shafts are much like elevator shafts, vertically on top of each other spanning multiple floors, except that the shaft is only physically big enough to allow the conductors to pass through the floors (whereas an elevator shaft is completely open).

On each floor the power is distributed further to provide energy for lighting, plugs and other tenant loads.

Most of the shared building loads 1230 of the commercial office building 100a are located on the roof. These loads include air conditioners, elevator motors, etc. The lease management office 1250 and engineering office floor 1240 are typically the only areas where the building owner or operator has office space. Therefore, gateways 150, computers 160, LAN 170 and WAN 171 connections for energy monitoring use are typically also located on these floors.

Energy consumption information may flow from the mesh networked devices (energy monitoring devices 120, repeaters 155 and gateways 150) through the computers 160, LAN 170, WAN 171 to a remote data processing center 1260 where usage information such as bills may be generated. This usage information 1270 is then returned to the building users 1280 through appropriate communication means. This information may also be delivered to corporate users 1290 such as the building owners/operators. A mesh network or other communications connection may be made to the service entrance meter 1215 in order that the computer 160 and/or remote data processing center 1260 may correlate the readings therefrom with those from the various energy monitoring devices 120. For instance if all loads within the office building 100a are monitored with energy monitoring devices 120, the combination of the energy monitoring devices readings should correlate with those of the service entrance meter 1215.

The building users may be presented with billing information that categorizes their actual energy usage and share of common loads by the remote data processing center 1260 by using the information from the energy monitoring devices 120.

Three phase transformers 1205 may be provided at various points in the office building 100a. In these cases it may be desirable to have energy monitoring devices 120 on both the inputs and outputs of the transformers to account for loses therein.

In one embodiment, the office building 100a, may contain one or more than one electrical closet shafts 1225. These shafts may split or be widely separated from one another. It may therefore be necessary to have multiple mesh networks within the building that comprises separate sets of energy monitoring devices 120, repeaters 155, gateways 150 and computers 160. Wireline segments or other means of bridging gaps in the mesh network may alternatively or in addition be used as described above.

When commissioning the system, battery powered mesh networking devices such as battery powered repeaters 155 may be temporarily installed in the building in order to “prove” out the network and identify areas where particular attention will have to be paid to establishing network links.

In addition, in some implementations, the low power RF signals of the mesh network may have difficulty traveling in a horizontal direction from the associated antennas of the devices 120 due to inherent limitations in the transmissive properties of such signals. Such limitations may result in a restricted transmission range. However, typically the vertical transmissive properties of the RF signals are acceptable. In one embodiment, the mesh network is formed via the vertical electrical shafts which allow for the vertically radiated RF signals to travel relatively unimpeded. The mesh network is carried to the roof of the facility or to another area having no substantial RF impediments, where the mesh network is bridged, either via a wired or wireless connection to other electrical shafts which have similarly formed mesh networks. In this way, the vertical transmissive properties of the RF signals are advantageously utilized and reliance on the horizontal transmissive properties are minimized. Alternatively, for buildings such as malls with a small number of floors, but a wide horizontal expanse, mounting devices 120 and/or repeaters 155 to form the mesh network along the roof also provides for an efficient network structure. Devices 120 monitoring rooftop loads such as air conditioners may perform “double duty” by extending the mesh network as well as monitoring a load. Repeaters 155 may be solar powered when mounted in rooftop locations or otherwise as described herein.

The following describes one exemplary implementation of a system incorporating aspects of the present invention. One exemplary implementation, which employs one or more of the disclosed embodiments, utilizes the ION 6100 Wireless Metering System, manufactured by Power Measurement, Ltd., located in Saanichton, British Columbia, Canada, which offers outstanding quality, versatility, and functionality in a low-cost wireless power and energy metering system ideal for sub-billing applications. This system is based on the PML ION 6100 Wireless Power Meter/monitoring device 120 and meets ANSI C12.16 Class 1 energy accuracy. This system may be utilized by Commercial (Office & Retail) Properties market in North America, and is ideal for customers who need revenue-accurate measurements for tenant sub-billing.

The system includes wireless metering devices, non-intrusive current transformers (CTs), and a central gateway that gathers, aggregates and logs meter data and exports it in an industry-standard XML format for integration into any software or billing system (including Power Measurement's ION EEM software).

The meters collect time-stamped, interval-based consumption data (kWh) from key sub-metering or sub-billing points throughout a building, then communicate the information to the central gateway (PC) via a proprietary wireless 900 MHz radio network. All meters are time-aligned with the gateway clock, so the system can also provide coincident demand readings.

The system offers customers a lower total cost of ownership (TCO) because: wireless communications eliminate the need to run costly communication wire and conduit throughout a facility; easy-to-use, split-core, current transformers (CTs) simply clamp onto existing wires for non-intrusive current measurements, simplifying installation; the ultra-compact meter design can attach to virtually any enclosure more than four inches deep with a single bolt; and automated gathering of meter data removes the need for manual meter reading.

The exemplary ION 6100 Wireless Metering System offers: high quality and accuracy, low installation costs (contributing to a lower Total Cost of Ownership); a complete system (meters, communications, gateway) (contributing to a lower Total Cost of Ownership); industry-standard XML data export for easy integration into any software system (such as the ION enterprise energy management system (“EEM”), manufactured by Power Measurement Ltd, located in Saanichton, British Columbia, Canada); and time synchronized for coincident demand calculations.

Unlike other power meters, which are sold separately and to a wide range of markets, this device is made available as part of a larger sub-billing solution for the commercial property market in North America.

The exemplary ION 6100 power meter offers:
Sub-Billing and Cost Allocation
   Costs (including usage and demand charges) can be fairly accounted for and apportioned among tenants appropriately, increasing tenant satisfaction and lowering operating costs.

Low Total Cost of Ownership (TCO)
The system offers customers a lower total cost of ownership (TCO) because:
   All necessary components can be purchased at once, on a single P.O.;
   Wireless communications eliminate the need to run costly communication wire and conduit throughout a facility;
   Easy-to-use, split-core, current transformers (CTs) simply clamp onto existing wires for non-intrusive current measurements, simplifying installation;
   Simple installation ensures no disruptions to regular business processes;
   Ultra-compact meter design can attach to virtually any enclosure more than two inches deep through a standard knockout with a ½″ threaded conduit lock ring;
   Automated gathering of meter data removes the need for manual meter reading.

Reliability
The ION 6100 offers a reliable “self-healing” approximately 900 MHz wireless radio network.
Each meter can relay a signal to the next closest meter, allowing signals to be easily transmitted from one end of a building to another. If a meter becomes unavailable, the other meters can communicate “around” it, so that there is no significant disruption in data transmission.

Useful Data
Besides sub-billing and cost allocation, data can be also used as an input to building automation and control systems, leveraging and maximizing the value of existing systems. The gateway can be used to capture a quick snapshot of overall operating performance and/or identify power problems at a particular load.
The ION 6100 Wireless Metering System is currently aimed at the North American commercial office and retail properties market, for buildings with greater than 500,000 square feet of leasable space and at least 20 tenants.
The key application for this system is sub-billing, but many commercial enterprises are also beginning to leverage these systems as core elements of a more comprehensive EEM solution focused on reducing energy costs and improving their net operating income (NOI) and overall asset value.

Value Proposition
For commercial building managers and owners in North America who need an accurate and automated system for fairly recovering energy costs from tenants. This system combines an accurate and reliable meter with a robust wireless communication network to create an automated sub-billing system with a low installation cost and a low total cost of ownership (TCO). Unlike traditional sub-metering devices, which must be manually read or that may lack the software required for efficient sub-billing or more powerful enterprise energy management.
The ION 6100 Wireless Metering System is an integrated end-to-end solution for tenant sub-metering and a key piece of a comprehensive Enterprise Energy Management (EEM) system

Exemplary relevant applications of the exemplary system include Primary Application: Sub-Billing

Typical scenario before installing ION 6100 Wireless Metering System solution:

| Existing Situation | No Metering | Existing Metering - No System |
|---|---|---|
| Desired | The property owner needs to recover the | The property owner needs to recover the |
| Outcome | costs of supplying electricity to the | costs of supplying electricity to the |
| | individual tenants for the lowest cost | individual tenants for the lowest cost |
| | possible. | possible. |
| Attempted | Energy and demand costs are either not | Meters are manually read either by a sub- |
| Approach | passed through to the tenants, or costs | billing service provider or by a |
| | are allocated to the tenants based on a | designated individual or individuals |
| | common formula - normally based on the | employed by the property management |
| | square footage of the tenant relative to | company. |
| | the total leasable space of the building. | |
| Interfering | Some States prohibit allocation methods | Even with existing metering that has |
| Factors | of cost recovery (Note: some prohibit | communications ability the cost of |
| | sub-billing as well). Traditionally, the | implementing communications can be |
| | costs to implement a sub-metering | high. |
| | system are high. | |
| Economic | Tenants are getting smarter and asking to | The labor and data integrity costs of |
| Consequences | be billed only for their own usage. | managing these manual systems are high. |
| | Allocation methods are inaccurate and | The lack of resolution in the data (i.e. one |
| | generally considered unfair. Accurate | monthly kWh reading) provides no |
| | and reliable sub-billing is somewhere | insight into the opportunities that may be |
| | between being a competitive and a de- | available to better manage costs. |
| | facto standard. | Allocation of coincident demand costs is |
| | | not possible. |

Typical scenario after installing the exemplary ION 6100 Wireless Metering System solution:

| | | |
|---|---|---|
| New | A low TCO, highly accurate and reliably | A low TCO, highly accurate and reliably |
| Approach | automated sub-billing system | automated sub-billing system |
| Enabling | Low cost metering devices that are | Low cost metering devices that are |
| Factors | inexpensive to install (non-intrusive CTs, | inexpensive to install (non-intrusive CTs, |
| | wireless communications) and maintain. | wireless communications) and maintain. |
| | Powerful and user-friendly data collection | Powerful and user-friendly data collection |
| | and billing software for providing detailed | and billing software for providing detailed |
| | cost data. | cost data. |
| Economic | Enables energy cost recovery in States that | Competitive or sustained advantage |
| Rewards | do not allow allocation methods. | relative to tenant satisfaction. Reduces |
| | Competitive or sustained advantage | costs due to manual reading and potential |
| | relative to tenant satisfaction. Detailed | data entry errors. Detailed interval data |
| | interval data enables accurate coincident | enables accurate coincident demand cost |
| | demand cost recovery. Detailed interval | recovery. Detailed interval data enables |
| | data enables insight to identify energy | insight to identify energy savings |
| | savings opportunities. | opportunities. |

Secondary Applications include: Contract and Bill Validation, which can help customers verify that energy management improvements are generating the projected payback, high-accuracy measurements can also be used for utility bill verification; and Cost Allocation which can help monitor cost centers right down to the tool level, identify opportunities for demand control, and check energy consumption patterns.

The following tables describe features and benefits of the exemplary ION 6100 monitoring device as both a metering device and as a gateway device.

ION 6100 Metering Device

| Feature | Advantage | Benefit |
|---|---|---|
| ION 6100 meter, | All the metering pieces in one neat | Simple to purchase, inexpensive to |
| NICTs, wireless | little package | install and operate - Installed costs of |
| communications | | $300 to $500 per metering point as |
| gateway | | compared with traditional sub-metering |
| | | solutions |
| Non-intrusive | The ION 6100 meters can be installed | Low installation cost, no installation |
| current & voltage | without requiring an outage in power to | disruption |
| transformers | the load | |
| (NICVTs/NICTs) | | |
| and/or voltage | | |
| displacement | | |
| connections | | |
| Wireless radio | No holes to drill, no conduit or wires to | Low installation costs, no |
| network | run, instant and automatic network | communication configuration on the |
| communications | configuration | device - Reliable “self-healing” |
| | | network communications |
| Exceeds ANSI | Accuracy is verified to national sub- | Costs can be fairly accounted for and |
| C12.16 (1%) | metering standards | apportioned appropriately |
| accuracy | | |
| standards or | | |
| appropriate local | | |
| standard. | | |
| 24 hour internal | Data is stored on the device as a | Low risk of data loss |
| data storage | backup in case of a temporary | |
| | communication interruption | |
| Devices are time | Independent device clocks are | Building demand charges can be |
| synchronized to | coordinated to enable accurate | accurately apportioned among tenants |
| the ION 6100 | coincident demand calculations | |
| Gateway for | | |
| coincident | | |
| demand | | |
| calculation | | |

ION 6100 Gateway

| Feature | Advantage | Benefit |
|---|---|---|
| All data is | Gateway software can | Data can be used for sub-billing, |
| collected | be configured to | as an input to building automation |
| in a | export data to | and control systems, etc. |
| central | multiple systems | |
| data file | | |
| and | | |
| exported | | |
| as | | |
| required | | |
| Diagnostic | Other power, energy, | The gateway can be used to capture a |
| data can | communication and | quick snapshot of overall operating |
| be | other diagnostic data | performance and/or identify power |
| requested | can be viewed on the | problems at a particular load. |
| from | gateway from any | |
| devices | device in the network | |

It is therefore intended that the foregoing detailed description be regarded as illustrative rather than limiting, and that it be understood that it is the following claims, including all equivalents, that are intended to define the spirit and scope of this invention.

We claim:

1. A method of monitoring electrical energy consumed by an electrical load, the method comprising:
sensing actual current flow in at least one power line which is supplying electrical energy to said load, said at least one power line being further characterized by an actual voltage value associated with said actual current flow;
generating an analog signal indicative of the amount of actual current flow sensed in said at least one power line;
converting said analog signal to a digital representation of said amount of said actual current flow;
providing an assumed voltage value of said at least one power line, wherein said assumed voltage value may be different than said actual voltage value, said assumed voltage comprising an approximation of said actual voltage value; and
calculating at least one measure of power consumption by said electrical load based on said digital representation, said calculating being further based on said assumed voltage value instead of said actual voltage value.

2. The method of claim 1, wherein said providing further comprises providing said assumed voltage value from a memory, said assumed voltage value comprising a digital representation of said approximation of said actual voltage value.

3. The method of claim 1, wherein said providing further comprises providing said assumed voltage value as an analog signal indicative thereof, the method further comprising converting said analog signal indicative of said assumed voltage value to a digital representation of said assumed voltage value, said calculating being based thereon.

4. The method of claim 1 wherein said providing further comprises:
providing an assumed magnitude value of said actual voltage value and a phase relationship between said actual current flow and said actual voltage value.

5. The method of claim 4, wherein said providing further comprises:
determining a magnitude of said actual current flow; and
adjusting said phase relationship based on said magnitude of said actual current flow.

6. The method of claim 4, wherein said providing further comprises determining said phase relationship by interpolation based on at least one known phase relationship, each of said at least one known phase relationship being associated with a particular possible magnitude value of said actual current flow.

7. The method of claim 1, wherein said digital representation further comprises a waveform representative of said actual current flow, said providing further comprising:
providing at least one characteristic current waveform representative of an approximation of said actual current flow, each of said at least one characteristic current waveform being associated with at least one assumed voltage waveform representative of an approximation of said actual voltage value, each of said at least one characteristic current waveform being associated with said at least one assumed voltage waveform.

8. The method of claim 7, wherein each of said at least one characteristic current waveform is associated with said at least one assumed voltage waveform by a time relationship associated with each of said at least one assumed voltage waveform.

9. The method of claim 7, wherein said providing further comprises:
comparing said waveform of said actual current flow with a subset of said at least one assumed current waveform; and
selecting an associated one of said at least one assumed voltage waveform associated with said at least one assumed current waveform which most closely approximates said waveform of said actual current flow.

10. The method of claim 7, wherein said sensing further comprises sensing said actual current flow during a transient event.

11. The method of claim 10, wherein said transient event comprises at least one of startup of said electrical load, shutdown of said electrical load, a surge, a sag or combinations thereof.

12. The method of claim 1, further comprising:
sensing said actual voltage value from said at least one power line;
generating an analog signal indicative of said actual voltage value sensed from said at least one power line;
converting said analog signal indicative of said actual voltage value to a digital representation of said actual voltage value; and
wherein said calculating further comprises calculating said at least one measure of power consumption based on said digital representation of said actual voltage value instead of said assumed voltage value.

13. The method of claim 12, wherein said calculating further comprises comparing said at least one measure of power consumption based on said assumed voltage value with said at least one measure of power consumption based on said actual voltage value.

14. The method of claim 15, further comprising:
providing an indication of historical accuracy of said at least one measure of power consumption based on said assumed voltage value.

15. The method of claim 12, wherein said sensing said actual voltage value further comprises sensing said actual voltage value without interrupting said at least one power line.

16. The method of claim 15, wherein said sensing said actual voltage value without interrupting said at least one power line further comprises piercing an insulative layer covering said at least one power line and contacting a conductor underneath said insulative layer.

17. The method of claim 1, further comprising:
communicating said at least one measure of power consumption to a data collection device by communicating said at least one measure of power consumption to a first monitoring device, said first monitoring device being coupled with a second monitoring device and operative to communicate said at least one measure of power consumption to said second monitoring device, said second monitoring device coupled with said data collection device and operative to communicate said at least one measure of power consumption to said data collection device.

18. A monitoring device for monitoring electrical energy consumed by an electrical load, the monitoring device comprising:
a current sensor operative to sense actual current flow in at least one power line which is supplying electrical energy to said load, said at least one power line being further characterized by an actual voltage value associated with said actual current flow, said current sensor being further operative to generate an analog signal indicative of the amount of actual current flow sensed in said at least one power line;
an analog to digital converter coupled with said current sensor and operative to convert said analog signal to a digital representation of said amount of said actual current flow;
a input operative to receive an assumed voltage value of said at least one power line, wherein said assumed voltage value may be different than said actual voltage value, said assumed voltage value comprising an approximation of said actual voltage value; and
a processor coupled with said analog to digital converter and said memory and operative to calculate at least one measure of power consumption by said electrical load based on said digital representation, said calculation being further based on said assumed voltage value instead of said actual voltage value.

19. The monitoring device of claim 18, wherein said input comprises a memory coupled with said processor, said memory storing said assumed voltage value, said assumed voltage value comprising a digital representation of said approximation of said actual voltage value.

20. The monitoring device of claim 18, wherein said input comprises an analog voltage input coupled with said analog to digital converter, said assumed voltage value being coupled with said analog voltage input, wherein said analog to digital converter is further operative to convert said assumed voltage value to a digital representation and transmit said digital representation of said assumed voltage value to said processor to be used in said calculation.

21. The monitoring device of claim 19, wherein said memory is operative to store an assumed magnitude value of said actual voltage value and a phase relationship between said actual current flow and said actual voltage value.

22. The monitoring device of claim 21, wherein said processor is further operative to determine a magnitude of said actual current flow and adjust said phase relationship based on said magnitude of said actual current flow.

23. The monitoring device of claim 21, wherein said processor is further operative to determine said phase relationship by interpolation based on at least one known phase relationship, each of said at least one known phase relationship being associated with a particular possible magnitude value of said actual current flow.

24. The monitoring device of claim 18, wherein said digital representation further comprises a waveform representative of said actual current flow, said monitoring device further comprising at least one characteristic current waveform representative of an approximation of said actual current flow and coupled with said processor, each of said at least one characteristic current waveform being associated with at least one assumed voltage waveform representative of an approximation of said actual voltage value, each of said at least one characteristic current waveform being associated with said at least one assumed voltage waveform.

25. The monitoring device of claim 24, wherein said processor is further operative to compare said waveform of said actual current flow with a subset of said at least one assumed current waveform and select an associated one of said at least one assumed voltage waveform associated with said at least one assumed current waveform which most closely approximates said waveform of said actual current flow.

26. The monitoring device of claim 25, wherein said selection by said processor is based on at least one of:
fuzzy logic;
artificial intelligence;
point by point comparison; or
combinations thereof.

27. The monitoring device of claim 24, wherein said current sensor is further operative to sense said actual current flow during a transient event.

28. The monitoring device of claim 27, wherein said transient event comprises at least one of startup of said electrical load, shutdown of said electrical load, a surge, a sag or combinations thereof.

29. The monitoring device of claim 18, further comprising:
a voltage sensor operative to sense said actual voltage value from said at least one power line and generate an analog signal indicative of said actual voltage value sensed from said at least one power line;
wherein said analog to digital converter is further coupled with said voltage sensor and further operative to convert said analog signal indicative of said actual voltage value to a digital representation of said actual voltage value; and
wherein said processor is further operative to calculate said at least one measure of power consumption based on said digital representation of said actual voltage value instead of said assumed voltage value.

30. The monitoring device of claim 29, wherein said processor is further operative to compare said at least one measure of power consumption based on said assumed voltage value with said at least one measure of power consumption based on said actual voltage value.

31. The monitoring device of claim 29, wherein said processor is further operative to provide an indication of historical accuracy of said at least one measure of power consumption based on said assumed voltage value.

32. The monitoring device of claim 29, wherein said voltage sensor is further operative to sense said actual voltage value further without interrupting said at least one power line.

33. The monitoring device of claim 32, wherein said voltage sensor is further operative to pierce an insulative layer covering said at least one power line and contact a conductor underneath said insulative layer.

34. The monitoring device of claim 18, further comprising:
a communications interface operative to communicate said at least one measure of power consumption to a data collection device by communicating said at least one measure of power consumption to a first remote monitoring device, said first remote monitoring device being coupled with a second remote monitoring device and operative to communicate said at least one measure of power consumption to said second monitoring device, said second remote monitoring device coupled with said data collection device and operative to communicate said at least one measure of power consumption to said data collection device.

35. A monitoring device for monitoring electrical energy consumed by an electrical load, the monitoring device comprising:
means for sensing actual current flow in at least one power line which is supplying electrical energy to said load, said at least one power line being further characterized by an actual voltage value associated with said actual current flow;
means for generating an analog signal indicative of the amount of actual current flow sensed in said at least one power line;
means for converting said analog signal to a digital representation of said amount of said actual current flow;
means for providing an assumed voltage value of said at least one power line, wherein said assumed voltage value may be different than said actual voltage value, said assumed voltage comprising an approximation of said actual voltage value; and
means for calculating at least one measure of power consumption by said electrical load based on said digital representation, said calculating being further based on said assumed voltage value instead of said actual voltage value.

36. The monitoring device of claim 35, wherein said means for providing an assumed voltage comprises a communications port.

37. The monitoring device of claim 35, wherein said input comprises a communications port.
